(19) United States
(12) Patent Application Publication
(10) Pub. No.: US 2020/0285537 A1
(43) Pub. Date: Sep. 10, 2020

(54) SEMICONDUCTOR CHIPS

(71) Applicant: SK hynix Inc., Icheon-si Gyeonggi-do (KR)

(72) Inventors: Sun Myung CHOI, Seoul (KR); Min Su PARK, Seoul (KR)

(73) Assignee: SK hynix Inc., Icheon-si Gyeonggi-do (KR)

(21) Appl. No.: 16/584,569

(22) Filed: Sep. 26, 2019

(30) Foreign Application Priority Data
Mar. 5, 2019 (KR) 10-2019-0025316

(51) Int. Cl. G06F 11/10; G11C 7/10

(52) U.S. Cl. CPC G06F 11/1004; G11C 7/1069; G11C 7/1045; G11C 7/109; G11C 7/1096; G11C 7/1063

(57) ABSTRACT

A semiconductor chip includes a first semiconductor device and a second semiconductor device. The first semiconductor device includes an error detection circuit. The second semiconductor device is stacked with the first semiconductor device and is electrically connected to the first semiconductor device via a first through electrode and a second through electrode. The first and second semiconductor devices are configured to receive or output first data and second data via the second through electrode according to an operation mode and are configured to detect errors of the first data and the second data using the error detection circuit.

### CROSS-REFERENCE TO RELATED APPLICATIONS

The present application claims priority under 35 U.S.C. § 119(a) to Korean Application No. 10-2019-0025316, filed on Mar. 5, 2019, which is incorporated herein by reference in its entirety.

### BACKGROUND

### 1. Technical Field

Embodiments of the present disclosure relate to semiconductor chips detecting errors of data that are received or outputted via through electrodes.

### 2. Related Art

Recently, various design schemes for receiving or outputting multi-bit data during each clock cycle have been used to improve an operation speed of semiconductor devices. If a data transmission speed of a semiconductor devices becomes faster, the probability of error occurrence increases while the data are transmitted in the semiconductor devices. This can create reliability issues during the transmission of data.

Whenever data are transmitted in semiconductor devices, error codes, which are capable of detecting occurrences of errors, may be generated and transmitted with the data to improve the reliability of data transmission. The error codes may include a cyclic redundancy check and an error detection code (EDC), which are capable of detecting errors, and an error correction code (ECC), which is capable of correcting errors.

Recently, three-dimensional semiconductor chips have been developed to increase the integration density of memory. Each of the three-dimensional semiconductor chips may be realized by vertically stacking a plurality of semiconductor devices to achieve a maximum integration density on a limited area.

Each of the three-dimensional semiconductor chips may be realized using a through silicon via (TSV) technique that electrically connects all of the stacked semiconductor devices with each other with silicon vias vertically penetrating the semiconductor devices. Accordingly, three-dimensional semiconductor chips fabricated using TSVs may reduce a packaging area as compared with three-dimensional semiconductor chips fabricated using bonding wires.

### SUMMARY

According to an embodiment, a semiconductor chip includes a first semiconductor device and a second semiconductor device. The first semiconductor device includes an error detection circuit. The second semiconductor device is stacked with the first semiconductor device and is electrically connected to the first semiconductor device via a first through electrode and a second through electrode. The first and second semiconductor devices are configured to receive or output first data and second data via the second through electrode according to an operation mode and are configured to detect errors of the first data and the second data using the error detection circuit.

According to another embodiment, a semiconductor chip includes a first semiconductor device and a second semiconductor device. The first semiconductor device includes a first error detection circuit. The second semiconductor device includes a second error detection circuit. The second semiconductor device is stacked with the first semiconductor device and is electrically connected to the first semiconductor device via a first through electrode and a second through electrode. The first and second semiconductor devices are configured to receive or output first data and second data via the second through electrode during a first write operation and a first read operation and are configured to detect errors of the first data and the second data using the first and second error detection circuits.

### BRIEF DESCRIPTION OF THE DRAWINGS

FIG. 1 is a block diagram illustrating a configuration of a semiconductor chip, according to an embodiment of the present disclosure.

FIG. 2 is a block diagram illustrating a configuration of a control circuit included in the semiconductor chip of FIG. 1.

FIG. 3 is a circuit diagram illustrating a configuration of a control signal generation circuit included in the control circuit of FIG. 2.

FIG. 4 is a table illustrating logic levels of signals generated by a register and a control signal generation circuit included in the control circuit of FIG. 2 according to an operation mode of the semiconductor chip of FIG. 1.

FIG. 5 is a circuit diagram illustrating a configuration of a first path control circuit included in the semiconductor chip of FIG. 1.

FIG. 6 is a circuit diagram illustrating a configuration of a second path control circuit included in the semiconductor chip of FIG. 1.

FIG. 7 illustrates a first write operation path of a semiconductor chip, according to an embodiment of the present disclosure.

FIG. 8 illustrates a first read operation path of a semiconductor chip, according to an embodiment of the present disclosure.

FIG. 9 illustrates a second write operation path of a semiconductor chip, according to an embodiment of the present disclosure.

FIG. 10 illustrates a second read operation path of a semiconductor chip, according to an embodiment of the present disclosure.

### DETAILED DESCRIPTION OF THE EMBODIMENTS

A limited number of possible embodiments of the present disclosure are described herein with reference to the accompanying drawings. These described embodiments are for illustrative purposes and are not intended to limit the scope of the present disclosure.

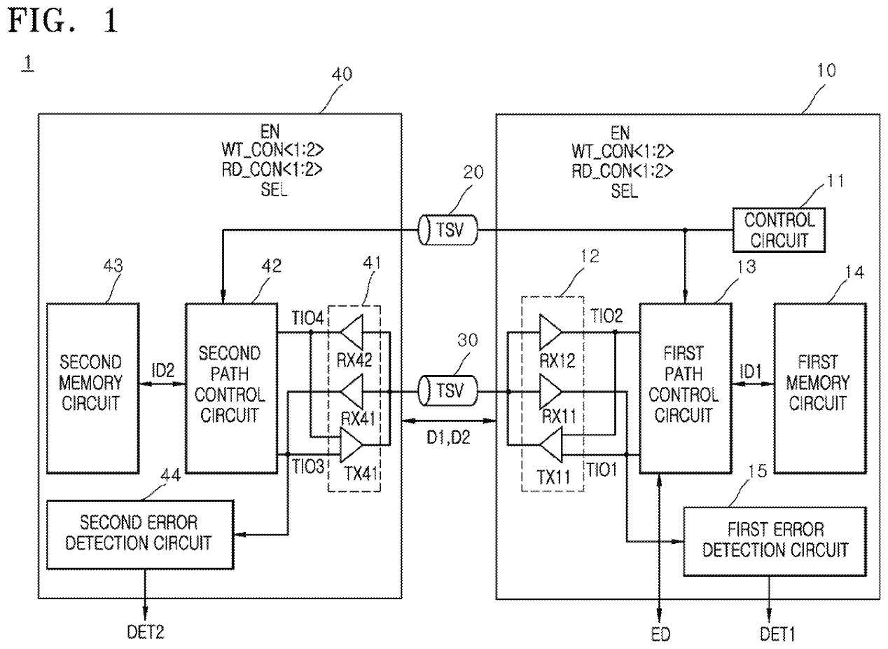

As illustrated in FIG. 1, a semiconductor chip 1 according to an embodiment may include a first semiconductor device 10, first through electrodes 20 such as through silicon vias (TSVs), second through electrodes 30 such as through silicon vias (TSVs), and a second semiconductor device 40.

The first semiconductor device 10 may include a control circuit 11, a first input/output (I/O) circuit 12, a first path control circuit 13, a first memory circuit 14, and a first error detection circuit 15.

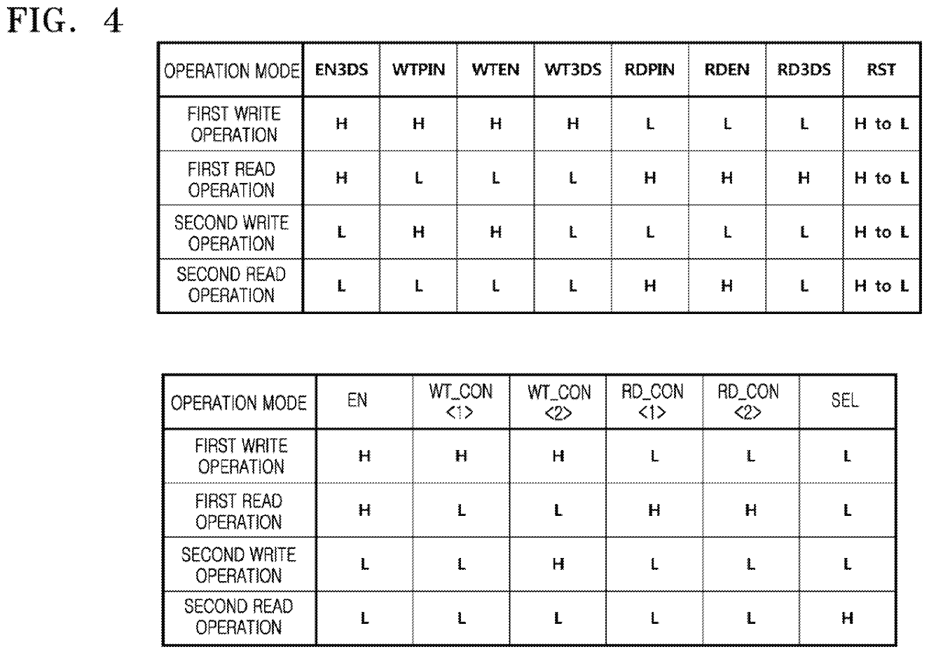

The control circuit 11 may generate an enablement signal EN, a first write control signal WT_CON<1>, a second write control signal WT_CON<2>, a first read control signal RD_CON<1>, a second read control signal RD_CON<2>, and a selection signal SEL, one of which is selectively enabled according to an operation mode. The control circuit 11 may output the enablement signal EN, the first write control signal WT_CON<1>, the second write control signal WT_CON<2>, the first read control signal RD_CON<1>, the second read control signal RD_CON<2>, and the selection signal SEL to the second semiconductor device 40 via the first through electrodes 20. Logic levels of the enablement signal EN, the first write control signal WT_CON<1>, the second write control signal WT_CON<2>, the first read control signal RD_CON<1>, the second read control signal RD_CON<2>, and the selection signal SEL, one of which is selectively enabled according to the operation mode is described in detail below with reference to FIG. 4.

The operation mode may include a first write operation, a first read operation, a second write operation, and a second read operation. The first write operation may be an operation that is performed to store first data D1 outputted from the first semiconductor device 10 into the second semiconductor device 40, and the first read operation may be an operation that is performed to output second data D2 outputted from the second semiconductor device 40 to an external device. In addition, the second write operation may be an operation that is performed to store external data ED provided by an external device into the first semiconductor device 10, and the second read operation may be an operation that is performed to output first internal data ID1 stored in the first semiconductor device 10 to the external device.

The first I/O circuit 12 may electrically connect the second through electrodes 30 to a first transmission I/O line TIO1 and a second transmission I/O line TIO2. The first I/O circuit 12 may output the first data D1 to the second semiconductor device 40 via the second through electrodes 30. The first I/O circuit 12 may receive the second data D2 from the second semiconductor device 40.

More specifically, the first I/O circuit 12 may be realized using a first transceiver TX11, a first receiver RX11, and a second receiver RX12. The first transceiver TX11 may output the first data D1 loaded on the first transmission I/O line TIO1 and the second transmission I/O line TIO2 to the second semiconductor device 40 via the second through electrodes 30. The first receiver RX11 may receive the second data D2 from the second semiconductor device 40 via the second through electrodes 30 and may output the second data D2 to the first transmission I/O line TIO1. The second receiver RX12 may receive the second data D2 from the second semiconductor device 40 via the second through electrodes 30 and may output the second data D2 to the second transmission I/O line TIO2.

The first path control circuit 13 may generate the first data D1 from the external data ED provided by an external device (not shown) to output the first data D1 to the first transmission I/O line TIO1 during the first write operation, based on the enablement signal EN, the first write control signal WT_CON<1>, the second write control signal WT_CON<2>, the first read control signal RD_CON<1>, the second read control signal RD_CON<2>, and the selection signal SEL. The first path control circuit 13 may generate the external data ED from the second data D2 loaded on the first transmission I/O line TIO1 to output the external data ED to the external device (not shown) during the first read operation, based on the enablement signal EN, the first write control signal WT_CON<1>, the second write control signal WT_CON<2>, the first read control signal RD_CON<1>, the second read control signal RD_CON<2>, and the selection signal SEL. The first path control circuit 13 may generate the first data D1 from the external data ED provided by the external device (not shown) to output the first data D1 to the first transmission I/O line TIO1 and may generate the first internal data ID1 from the external data ED during the second write operation, based on the enablement signal EN, the first write control signal WT_CON<1>, the second write control signal WT_CON<2>, the first read control signal RD_CON<1>, the second read control signal RD_CON<2>, and the selection signal SEL. The first path control circuit 13 may generate the first data D1 from the first internal data ID1 to output the first data D1 to the first transmission I/O line TIO1 and may generate the external data ED from the first internal data ID1 to output the external data ED to the external device (not shown) during the second read operation, based on the enablement signal EN, the first write control signal WT_CON<1>, the second write control signal WT_CON<2>, the first read control signal RD_CON<1>, the second read control signal RD_CON<2>, and the selection signal SEL.

The first memory circuit 14 may store the first internal data ID1 during the second write operation. The first memory circuit 14 may output the first internal data ID1 stored therein during the second read operation.

The first error detection circuit 15 may detect errors of the first data D1 and the second data D2 loaded on the first transmission I/O line TIO1 to generate a first detection signal DET1. The first error detection circuit 15 may output the first detection signal DET1 to the external device (not shown). The first error detection circuit 15 may detect the errors of the first data D1 and the second data D2 to generate the first detection signal DET1 during the first write operation, the first read operation, the second write operation, and the second read operation. The first error detection circuit 15 may detect the errors of the first data D1 and the second data D2 to generate the first detection signal DET1 through a cyclic redundancy check.

The second semiconductor device 40 may include a second I/O circuit 41, a second path control circuit 42, a second memory circuit 43, and a second error detection circuit 44.

The second I/O circuit 41 may electrically connect the second through electrodes 30 to a third transmission I/O line TIO3 and a fourth transmission I/O line T104. The second I/O circuit 41 may output the second data D2 to the first semiconductor device 10 via the second through electrodes 30. The second I/O circuit 41 may receive the first data D1 from the first semiconductor device 10.

More specifically, the second I/O circuit 41 may be realized using a second transceiver TX41, a third receiver RX41, and a fourth receiver RX42. The second transceiver TX41 may output the second data D2 loaded on the third transmission I/O line TIO3 and the fourth transmission I/O line TIO4 to the first semiconductor device 10 via the second through electrodes 30. The third receiver RX41 may receive the first data D1 from the first semiconductor device 10 via the second through electrodes 30 and may output the first data D1 to the third transmission I/O line TIO3. The fourth receiver RX42 may receive the first data D1 from the first semiconductor device 10 via the second through electrodes 30 and may output the first data D1 to the fourth transmission I/O line TIO4.

The second path control circuit 42 may receive the first data D1 through the third transmission I/O line TIO3 to generate second internal data ID2 during the first write operation, based on the enablement signal EN, the first write control signal WT_CON<1>, the second write control signal WT_CON<2>, the first read control signal RD_CON<1>, the second read control signal RD_CON<2>, and the selection signal SEL which are inputted via the first through electrodes 20. The second path control circuit 42 may output the second internal data ID2 as the second data D2 through the third transmission I/O line TIO3 during the first read operation, based on the enablement signal EN, the first write control signal WT_CON<1>, the second write control signal WT_CON<2>, the first read control signal RD_CON<1>, the second read control signal RD_CON<2>, and the selection signal SEL which are inputted via the first through electrodes 20.

The second memory circuit 43 may store the second internal data ID2 during the first write operation. The second memory circuit 43 may output the second internal data ID2 stored therein during the first read operation.

The second error detection circuit 44 may detect errors of the first data D1 and the second data D2 loaded on the third transmission I/O line TIO3 to generate a second detection signal DET2. The second error detection circuit 44 may output the second detection signal DET2 to the external device (not shown). The second error detection circuit 44 may detect the errors of the first data D1 and the second data D2 to generate the second detection signal DET2 during the first write operation and the first read operation. The second error detection circuit 44 may detect the errors of the first data D1 and the second data D2 to generate the second detection signal DET2 through a cyclic redundancy check. Although the second error detection circuit 44 is realized to generate the second detection signal DET2 by detecting the errors of the first data D1 and the second data D2 during the first write operation and the first read operation, the second error detection circuit 44 may be realized not to operate while the first error detection circuit 15 operates. In the event that the second semiconductor device 40 independently performs a write operation and a read operation, the second error detection circuit 44 may be realized to generate the second detection signal DET2 by detecting the errors of data loaded on the third transmission I/O line TIO3.

Meanwhile, although the first and second semiconductor devices 10 and 40 are illustrated to be laterally adjacent to be each other in FIG. 1, the first and second semiconductor devices 10 and 40 may be vertically stacked and may be electrically connected to each other via the first and second through electrodes 20 and 30. In addition, although FIG. 1 illustrates an example in which the semiconductor chip 1 includes the first and second semiconductor devices 10 and 40, the semiconductor chip 1 may be configured to include three or more semiconductor devices, which may be sequentially stacked, according to different embodiments.

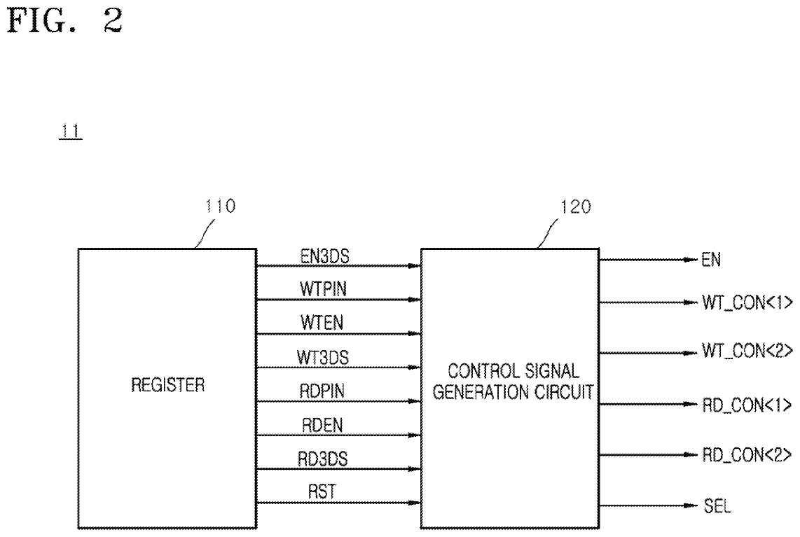

Referring to FIG. 2, the control circuit 11 may include a register 110 and a control signal generation circuit 120.

The register 110 may generate a mode enablement signal EN3DS, a first write mode signal WTPIN, a second write mode signal WTEN, a third write mode signal WT3DS, a first read mode signal RDPIN, a second read mode signal RDEN, a third read mode signal RD3DS, and a reset signal RST. The mode enablement signal EN3DS may include information on the first write operation, the first read operation, the second write operation, and the second read operation. The register 110 may be realized using a mode register set (MRS) including a plurality of registers, thereby storing information on the operation modes of the semiconductor chip 1.

The control signal generation circuit 120 may generate the enablement signal EN, the first write control signal WT_CON<1>, the second write control signal WT_CON<2>, the first read control signal RD_CON<1>, the second read control signal RD_CON<2>, and the selection signal SEL, one of which is selectively enabled according to a logic level combination of the mode enablement signal EN3DS, the first write mode signal WTPIN, the second write mode signal WTEN, the third write mode signal WT3DS, the first read mode signal RDPIN, the second read mode signal RDEN, the third read mode signal RD3DS, and the reset signal RST.

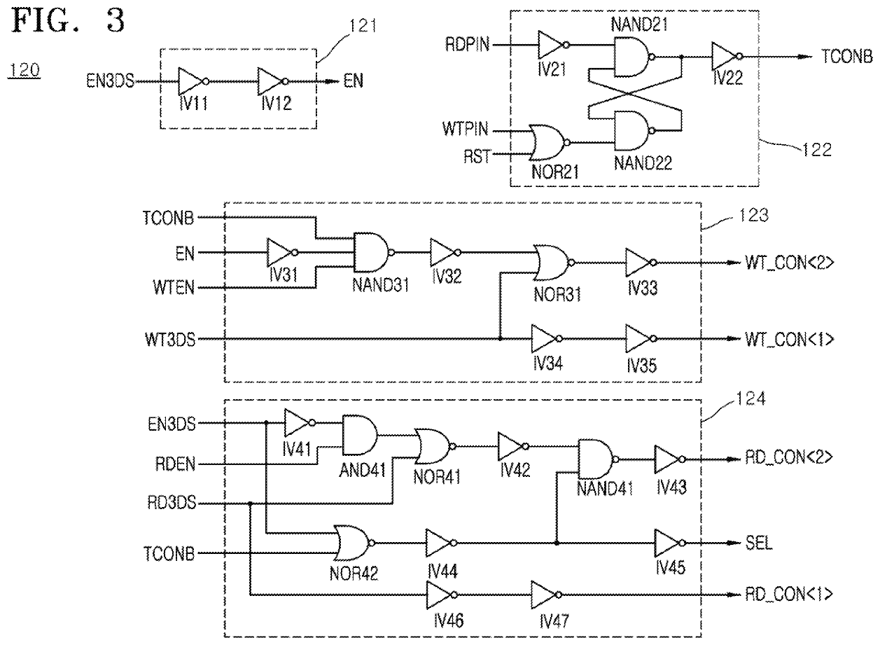

Referring to FIG. 3, the control signal generation circuit 120 may include an enablement signal generation circuit 121, a transmission control signal generation circuit 122, a write control signal generation circuit 123, and a read control signal generation circuit 124.

The enablement signal generation circuit 121 may be realized using inverters IV11 and IV12 which are coupled in series. The enablement signal generation circuit 121 may delay the mode enablement signal EN3DS to generate the enablement signal EN.

The transmission control signal generation circuit 122 may be realized using inverters IV21 and IV22, a NOR gate NOR21, and NAND gates NAND21 and NAND22. The transmission control signal generation circuit 122 may generate a transmission control signal TCONB which is enabled to have a logic “low” level when the first read mode signal RDPIN inputted to the transmission control signal generation circuit 122 has a logic “high” level. The transmission control signal generation circuit 122 may generate the transmission control signal TCONB which is disabled to have a logic “high” level when any one of the reset signal RST and the first write mode signal WTPIN inputted to the transmission control signal generation circuit 122 has a logic “high” level.

The write control signal generation circuit 123 may be realized using inverters IV31, IV32, IV33, IV34, and IV35, a NAND gate NAND31, and a NOR gate NOR31. The write control signal generation circuit 123 may generate the first write control signal WT_CON<1> and the second write control signal WT_CON<2>, one of which is selectively enabled according to a logic level combination of the enablement signal EN, the second write mode signal WTEN, and the third write mode signal WT3DS when the transmission control signal TCONB is disabled to have a logic “high” level.

The read control signal generation circuit 124 may be realized using inverters IV41, IV42, IV43, IV44, IV45, IV46, and IV47, an AND gate AND41, NOR gates NOR41 and NOR42, and a NAND gate NAND41. The read control signal generation circuit 124 may generate the first read control signal RD_CON<1> and the second read control signal RD_CON<2>, one of which is selectively enabled according to a logic level combination of the mode enablement signal EN3DS, the second read mode signal RDEN, and the third read mode signal RD3DS. The read control signal generation circuit 124 may generate the selection signal SEL which is enabled to have a logic “high” level when the mode enablement signal EN3DS is disabled to have a logic “low” level and the transmission control signal TCONB is enabled to have a logic “low” level.

More specifically, logic levels of the signals generated by the register 110 and the control signal generation circuit 120 according to the operation mode are described with reference to FIG. 4.

Referring to FIG. 4, the register 110 may generate the mode enablement signal EN3DS having a logic “high(H)” level, the first write mode signal WTPIN having a logic “high(H)” level, the second write mode signal WTEN having a logic “high(H)” level, the third write mode signal WT3DS having a logic “high(H)” level, the first read mode signal RDPIN having a logic “low(L)” level, the second read mode signal RDEN having a logic “low(L)” level, the third read mode signal RD3DS having a logic “low(L)” level, and the reset signal RST toggling from a logic “high(H)” level to a logic “low(L)” level during the first write operation.

The control signal generation circuit 120 may receive the mode enablement signal EN3DS, the first write mode signal WTPIN, the second write mode signal WTEN, the third write mode signal WT3DS, the first read mode signal RDPIN, the second read mode signal RDEN, the third read mode signal RD3DS, and the reset signal RST to generate the enablement signal EN having a logic “high(H)” level, the first write control signal WT_CON<1> having a logic “high(H)” level, the second write control signal WT_CON<2> having a logic “high(H)” level, the first read control signal RD_CON<1> having a logic “low(L)” level, the second read control signal RD_CON<2> having a logic “low(L)” level, and the selection signal SEL having a logic “low(L)” level during the first write operation.

The register 110 may generate the mode enablement signal EN3DS having a logic “high(H)” level, the first write mode signal WTPIN having a logic “low(L)” level, the second write mode signal WTEN having a logic “low(L)” level, the third write mode signal WT3DS having a logic “low(L)” level, the first read mode signal RDPIN having a logic “high(H)” level, the second read mode signal RDEN having a logic “high(H)” level, the third read mode signal RD3DS having a logic “high(H)” level, and the reset signal RST toggling from a logic “high(H)” level to a logic “low(L)” level during the first read operation.

The control signal generation circuit 120 may receive the mode enablement signal EN3DS, the first write mode signal WTPIN, the second write mode signal WTEN, the third write mode signal WT3DS, the first read mode signal RDPIN, the second read mode signal RDEN, the third read mode signal RD3DS, and the reset signal RST to generate the enablement signal EN having a logic “high(H)” level, the first write control signal WT_CON<1> having a logic “low(L)” level, the second write control signal WT_CON<2> having a logic “low(L)” level, the first read control signal RD_CON<1> having a logic “high(H)” level, the second read control signal RD_CON<2> having a logic “high(H)” level, and the selection signal SEL having a logic “low(L)” level during the first read operation.

The register 110 may generate the mode enablement signal EN3DS having a logic “low(L)” level, the first write mode signal WTPIN having a logic “high(H)” level, the second write mode signal WTEN having a logic “high(H)” level, the third write mode signal WT3DS having a logic “low(L)” level, the first read mode signal RDPIN having a logic “low(L)” level, the second read mode signal RDEN having a logic “low(L)” level, the third read mode signal RD3DS having a logic “low(L)” level, and the reset signal RST toggling from a logic “high(H)” level to a logic “low(L)” level during the second write operation.

The control signal generation circuit 120 may receive the mode enablement signal EN3DS, the first write mode signal WTPIN, the second write mode signal WTEN, the third write mode signal WT3DS, the first read mode signal RDPIN, the second read mode signal RDEN, the third read mode signal RD3DS, and the reset signal RST to generate the enablement signal EN having a logic “low(L)” level, the first write control signal WT_CON<1> having a logic “low(L)” level, the second write control signal WT_CON<2> having a logic “high(H)” level, the first read control signal RD_CON<1> having a logic “low(L)” level, the second read control signal RD_CON<2> having a logic “low(L)” level, and the selection signal SEL having a logic “low(L)” level during the second write operation.

The register 110 may generate the mode enablement signal EN3DS having a logic “low(L)” level, the first write mode signal WTPIN having a logic “low(L)” level, the second write mode signal WTEN having a logic “low(L)” level, the third write mode signal WT3DS having a logic “low(L)” level, the first read mode signal RDPIN having a logic “high(H)” level, the second read mode signal RDEN having a logic “high(H)” level, the third read mode signal RD3DS having a logic “low(L)” level, and the reset signal RST toggling from a logic “high(H)” level to a logic “low(L)” level during the second read operation.

The control signal generation circuit 120 may receive the mode enablement signal EN3DS, the first write mode signal WTPIN, the second write mode signal WTEN, the third write mode signal WT3DS, the first read mode signal RDPIN, the second read mode signal RDEN, the third read mode signal RD3DS, and the reset signal RST to generate the enablement signal EN having a logic “low(L)” level, the first write control signal WT_CON<1> having a logic “low(L)” level, the second write control signal WT_CON<2> having a logic “low(L)” level, the first read control signal RD_CON<1> having a logic “low(L)” level, the second read control signal RD_CON<2> having a logic “low(L)” level, and the selection signal SEL having a logic “high(H)” level during the second read operation.

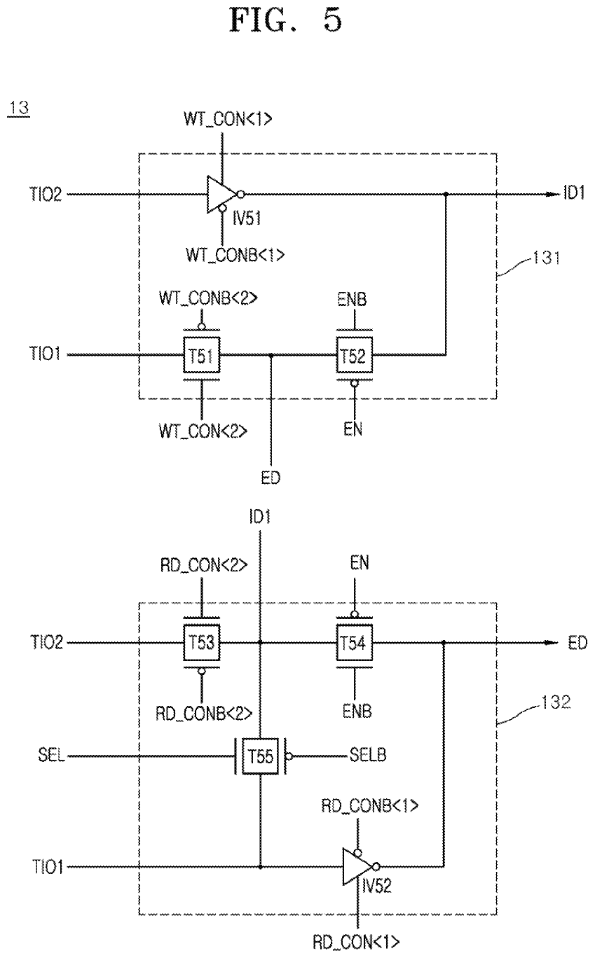

Referring to FIG. 5, the first path control circuit 13 may include a first write path control circuit 131 and a first read path control circuit 132.

The first write path control circuit 131 may be realized using a first buffer IV51, a first transfer gate T51, and a second transfer gate T52.

The first buffer IV51 may be turned on when the first write control signal WT_CON<1> has a logic “high” level and a first inverted write control signal WT_CONB<1> has a logic “low” level. Thus, the first buffer IV51 may inversely buffer a signal loaded on the second transmission I/O line TIO2 to generate the first internal data ID1 when the first write control signal WT_CON<1> has a logic “high” level and the first inverted write control signal WT_CONB<1> has a logic “low” level. The first transfer gate T51 may be turned on when the second write control signal WT_CON<2> has a logic “high” level and a second inverted write control signal WT_CONB<2> has a logic “low” level. Thus, the first transfer gate T51 may generate the first data D1 from the external data ED to output the first data D1 through the first transmission I/O line TIO1 when the second write control signal WT_CON<2> has a logic “high” level and the second inverted write control signal WT_CONB<2> has a logic “low” level. The second transfer gate T52 may be turned on to generate the first internal data ID1 from the external data ED when the enablement signal EN has a logic “low” level and an inverted enablement signal ENB has a logic “high” level. The first inverted write control signal WT_CONB<1> may be generated by inverting a logic level of the first write control signal WT_CON<1>, and the second inverted write control signal WT_CONB<2> may be generated by inverting a logic level of the second write control signal WT_CON<2>. Moreover, the inverted enablement signal ENB may be generated by inverting a logic level of the enablement signal EN.

The first read path control circuit 132 may be realized using a second buffer IV52, a third transfer gate T53, a fourth transfer gate T54, and a fifth transfer gate T55.

The second buffer IV52 may be turned on when the first read control signal RD_CON<1> has a logic “high” level and a first inverted read control signal RD_CONB<1> has a logic “low” level. Thus, the second buffer IV52 may inversely buffer a signal loaded on the first transmission I/O line TIO1 to generate the external data ED when the first read control signal RD_CON<1> has a logic “high” is level and the first inverted read control signal RD_CONB<1> has a logic “low” level. The third transfer gate T53 may be turned on to output the first internal data ID1 through the second transmission I/O line TIO2 when the second read control signal RD_CON<2> has a logic “high” level and a second inverted read control signal RD_CONB<2> has a logic “low” level. The fourth transfer gate T54 may be turned on to generate the external data ED from the first internal data ID1 when the enablement signal EN has a logic “low” level and the inverted enablement signal ENB has a logic “high” level. The fifth transfer gate T55 may be turned on to output the first internal data ID1 through the first transmission I/O line TIO1 when the selection signal SEL has a logic “high” level and an inverted selection signal SELB has a logic “low” level. The first inverted read control signal RD_CONB<1> may be generated by inverting a logic level of the first read control signal RD_CON<1>, and the second inverted read control signal RD_CONB<2> may be generated by inverting a logic level of the second read control signal RD_CON<2>. Moreover, the inverted selection signal SELB may be generated by inverting a logic level of the selection signal SEL.

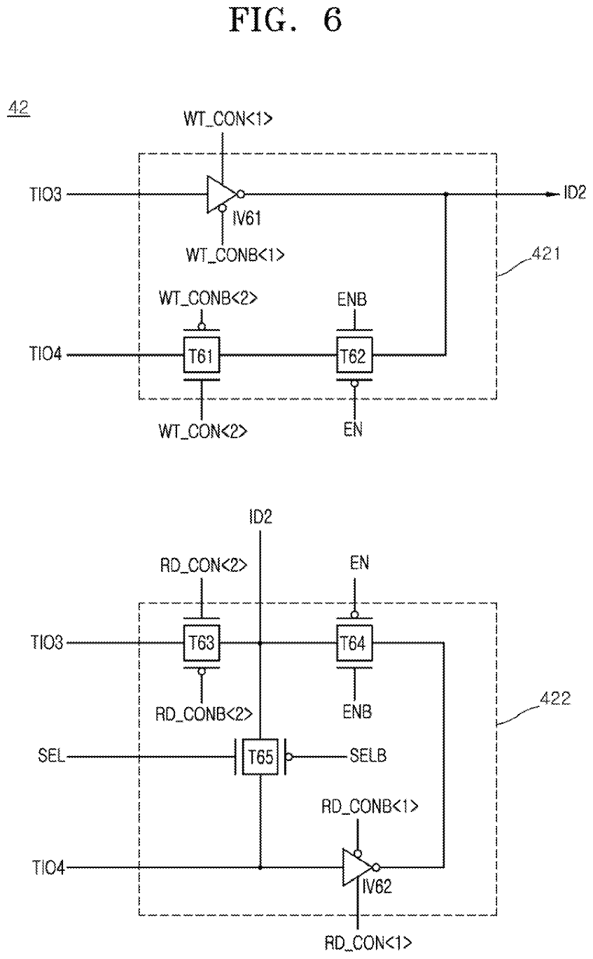

Referring to FIG. 6, the second path control circuit 42 may include a second write path control circuit 421 and a second read path control circuit 422.

The second write path control circuit 421 may be realized using a third buffer IV61, a sixth transfer gate T61, and a seventh transfer gate T62.

The third buffer IV61 may be turned on when the first write control signal WT_CON<1> has a logic “high” level and the first inverted write control signal WT_CONB<1> has a logic “low” level. Thus, the third buffer IV61 may inversely buffer a signal loaded on the third transmission I/O line TIO3 to generate the second internal data ID2 when the first write control signal WT_CON<1> has a logic “high” level and the first inverted write control signal WT_CONB<1> has a logic “low” level. The sixth transfer gate T61 may be turned on when the second write control signal WT_CON<2> has a logic “high” level and the second inverted write control signal WT_CONB<2> has a logic “low” level. The seventh transfer gate T62 may be turned on when the enablement signal EN has a logic “low” level and the inverted enablement signal ENB has a logic “high” level.

The second read path control circuit 422 may be realized using a fourth buffer IV62, an eighth transfer gate T63, a ninth transfer gate T64, and a tenth transfer gate T65.

The fourth buffer IV62 may be turned on when the first read control signal RD_CON<1> has a logic “high” level and the first inverted read control signal RD_CONB<1> has a logic “low” level. The eighth transfer gate T63 may be turned on to output the second internal data ID2 through the third transmission I/O line TIO3 when the second read control signal RD_CON<2> has a logic “high” level and the second inverted read control signal RD_CONB<2> has a logic “low” level. The ninth transfer gate T64 may be turned on when the enablement signal EN has a logic “low” level and the inverted enablement signal ENB has a logic “high” level. The tenth transfer gate T65 may be turned on to output the second internal data ID2 through the fourth transmission I/O line TIO4 when the selection signal SEL has a logic “high” level and the inverted selection signal SELB has a logic “low” level.

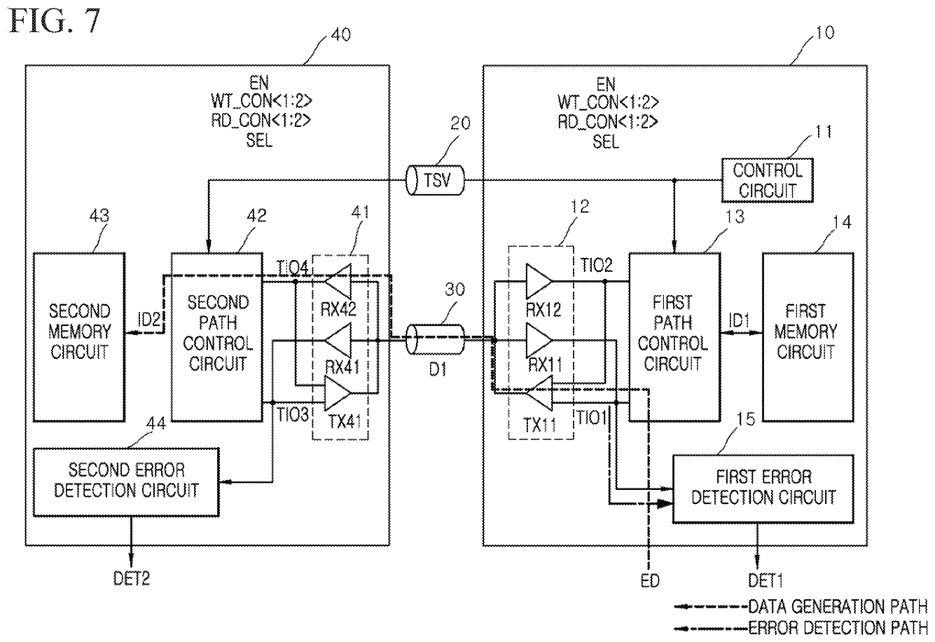

An operation for generating the first data D1 and an operation for detecting errors of the first data D1 through a first write operation path of the semiconductor chip 1 are described with reference to FIG. 7.

Referring to FIG. 7, the control circuit 11 may generate the enablement signal EN having a logic “high(H)” level, the first write control signal WT_CON<1> having a logic “high(H)” level, the second write control signal WT_CON<2> having a logic “high(H)” level, the first read control signal RD_CON<1> having a logic “low(L)” level, the second read control signal RD_CON<2> having a logic “low(L)” level, and the selection signal SEL having a logic “low(L)” level during the first write operation.

The first path control circuit 13 may generate the first data D1 from the external data ED provided by an external device (not shown) to output the first data D1 to the first transmission I/O line TIO1 based on the second write control signal WT_CON<2> having a logic “high(H)” level during the first write operation.

The first I/O circuit 12 may output the first data D1 to the second semiconductor device 40 through the second through electrodes 30.

The first error detection circuit 15 may detect errors of the first data D1 loaded on the first transmission I/O line TIO1 to generate and output the first detection signal DET1 to an external device.

The second I/O circuit 41 may receive the first data D1 from the first semiconductor device 10 via the second through electrodes 30 and may output the first data D1 to the third and fourth transmission I/O lines TIO3 and TIO4.

The second path control circuit 42 may receive the first data D1 through the third transmission I/O line TIO3 to generate the second internal data ID2 based on the first write control signal WT_CON<1> having a logic “high(H)” level, which is inputted via the first through electrodes 20.

The second memory circuit 43 may store the second internal data ID2 during the first write operation.

As described above, the semiconductor chip 1 may detect the errors of the first data D1 loaded on the first transmission I/O line TIO1 to generate and output the first detection signal DET1 during the first write operation.

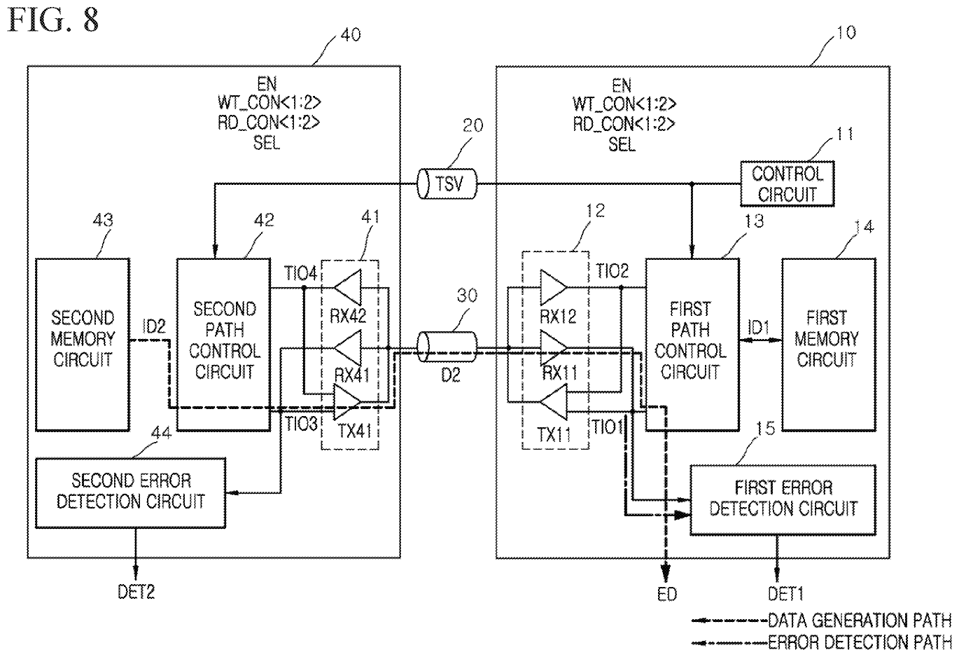

An operation for generating the second data D2 and an operation for detecting errors of the second data D2 through a first read operation path of the semiconductor chip 1 are described with reference to FIG. 8.

Referring to FIG. 8, the control circuit 11 may generate the enablement signal EN having a logic “high(H)” level, the first write control signal WT_CON<1> having a logic “low(L)” level, the second write control signal WT_CON<2> having a logic “low(L)” level, the first read control signal RD_CON<1> having a logic “high(H)” level, the second read control signal RD_CON<2> having a logic “high(H)” level, and the selection signal SEL having a logic “low(L)” level during the first read operation.

The second memory circuit 43 may output the second internal data ID2 during the first read operation.

The second path control circuit 42 may output the second internal data ID2 as the second data D2 through the third transmission I/O line TIO3 based on the second read control signal RD_CON<2> having a logic “high(H)” level, which is inputted via the first through electrodes 20.

The second I/O circuit 41 may output the second data D2 to the first semiconductor device 10 via the second through electrodes 30.

The first I/O circuit 12 may receive the second data D2 from the second semiconductor device 40 via the second through electrodes 30 and may output the second data D2 to the first transmission I/O line TIO1.

The first error detection circuit 15 may detect errors of the second data D2 loaded on the first transmission I/O line TIO1 to generate and output the first detection signal DET1 to an external device.

The first path control circuit 13 may generate the external data ED from the second data D2 loaded on the first transmission I/O line TIO1 to output the external data ED to an external device based on the first read control signal RD_CON<1> having a logic “high(H)” level during the first read operation.

As described above, the semiconductor chip 1 may detect the errors of the second data D2 loaded on the first transmission I/O line TIO1 to generate and output the first detection signal DET1 during the first read operation.

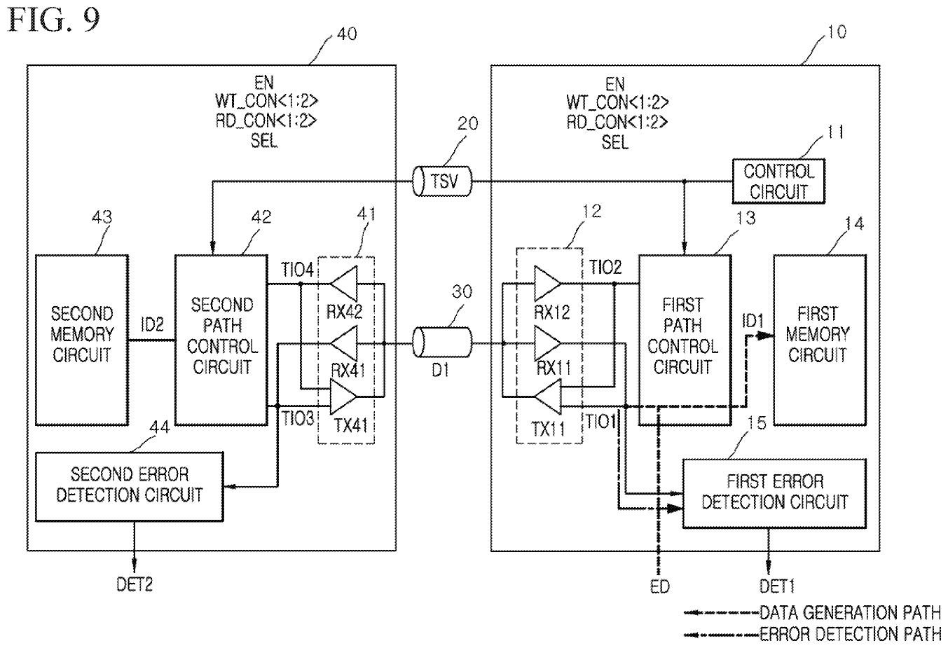

An operation for generating the first data D1 and an operation for detecting errors of the first data D1 through a second write operation path of the semiconductor chip 1 are described with reference to FIG. 9.

Referring to FIG. 9, the control circuit 11 may generate the enablement signal EN having a logic “low(L)” level, the first write control signal WT_CON<1> having a logic “low(L)” level, the second write control signal WT_CON<2> having a logic “high(H)” level, the first read control signal RD_CON<1> having a logic “low(L)” level, the second read control signal RD_CON<2> having a logic “low(L)” level, and the selection signal SEL having a logic “low(L)” level during the second write operation.

The first path control circuit 13 may generate the first data D1 from the external data ED provided by an external device (not shown) to output the first data D1 to the first transmission I/O line TIO1 based on the second write control signal WT_CON<2> having a logic “high(H)” level during the second write operation. The first path control circuit 13 may generate the first internal data ID1 from the external data ED based on the enablement signal EN having a logic “low(L)” level during the second write operation.

The first error detection circuit 15 may detect errors of the first data D1 loaded on the first transmission I/O line TIO1 to generate and output the first detection signal DET1 to an external device.

The first memory circuit 14 may store the first internal data ID1 during the second write operation.

As described above, the semiconductor chip 1 may detect the errors of the first data D1 loaded on the first transmission I/O line TIO1 to generate and output the first detection signal DET1 during the second write operation.

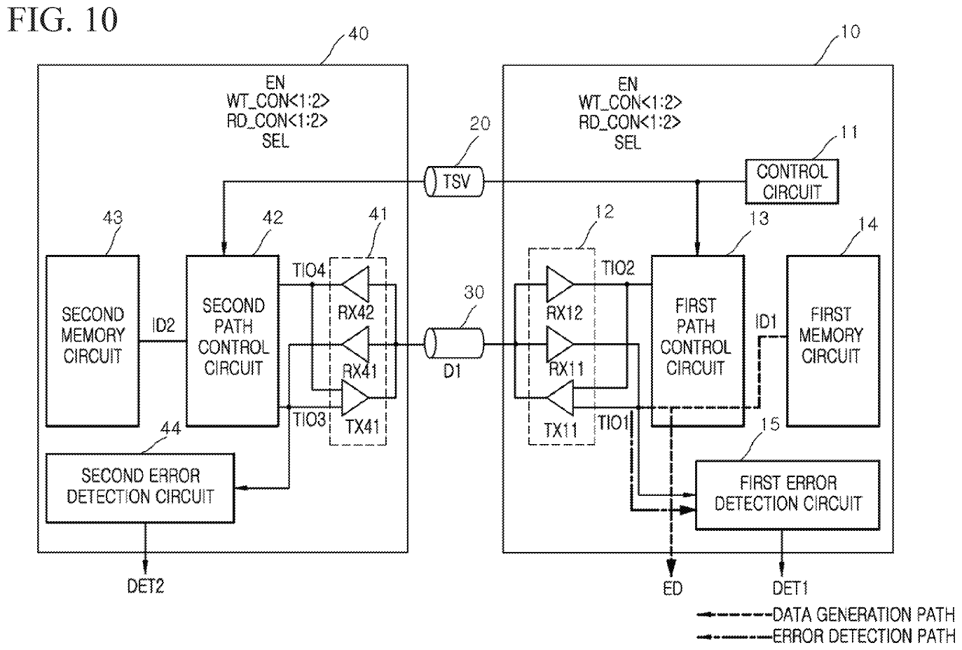

An operation for generating the first data D1 and an operation for detecting errors of the first data D1 through a second read operation path of the semiconductor chip 1 are described with reference to FIG. 10.

Referring to FIG. 10, the control circuit 11 may generate the enablement signal EN having a logic “low(L)” level, the first write control signal WT_CON<1> having a logic “low(L)” level, the second write control signal WT_CON<2> having a logic “low(L)” level, the first read control signal RD_CON<1> having a logic “low(L)” level, the second read control signal RD_CON<2> having a logic “low(L)” level, and the selection signal SEL having a logic “high(H)” level during the second read operation.

The first memory circuit 14 may output the first internal data ID1 during the second read operation.

The first path control circuit 13 may generate and output the external data ED from the first internal data ID1 based on the enablement signal EN having a logic “low(L)” level during the second read operation. The first path control circuit 13 may generate the first data D1 from the first internal data ID1 to output the first data D1 to the first transmission I/O line TIO1 based on the selection signal SEL having a logic “high(H)” level during the second read operation.

The first error detection circuit 15 may detect errors of the first data D1 loaded on the first transmission I/O line TIO1 to generate and output the first detection signal DET1 to an external device.

As described above, the semiconductor chip 1 may detect the errors of the first data D1 loaded on the first transmission I/O line TIO1 to generate and output the first detection signal DET1 during the second read operation.

According to an embodiment described above, a semiconductor chip may have improved efficiency of detecting errors of data by detecting the errors of the data, which are inputted or outputted, using a single error detection circuit during a write operation or a read operation for a plurality of semiconductor devices sequentially stacked in the semiconductor chip.

What is claimed is:

1. A semiconductor chip comprising:
a first semiconductor device comprising an error detection circuit; and
a second semiconductor device stacked with the first semiconductor device and electrically connected to the first semiconductor device via a first through electrode and a second through electrode,
wherein the first and second semiconductor devices are configured to at least one of receive and output first data and second data via the second through electrode according to an operation mode and are configured to detect errors of the first data and the second data using the error detection circuit.

2. The semiconductor chip of claim 1, wherein:
the operation mode comprises one of a first write operation, a second write operation, a second write operation, and a second read operation;
the first write operation is performed to store the first data outputted by the first semiconductor device into the second semiconductor device;
the first read operation is performed to output the second data outputted by the second semiconductor device to an external device;
the second write operation is performed to store external data provided by the external device into the first semiconductor device; and
the second read operation is performed to output internal data stored in the first semiconductor device to the external device.

3. The semiconductor chip of claim 1, wherein, during a first write operation:
the first semiconductor device is configured to generate the first data from first external data provided by an external device and is configured to detect errors of the first data using the error detection circuit; and
the second semiconductor device is configured to store first internal data generated from the first data.

4. The semiconductor chip of claim 1, wherein, during a first read operation:
the second semiconductor device is configured to output second internal data stored in the second semiconductor device as the second data via the second through electrode; and
the first semiconductor device is configured to detect errors of the second data using the error detection circuit and is configured to output the second data as second external data.

5. The semiconductor chip of claim 1, wherein, during a second write operation, the first semiconductor device is configured to:
generate the first data from third external data provided by an external device;
detect errors of the first data using the error detection circuit; and
store third internal data generated from the third external data.

6. The semiconductor chip of claim 1, wherein, during a second read operation, the first semiconductor device is configured to:
generate the first data from fourth internal data stored in the first semiconductor device;
detect errors of the first data using the error detection circuit; and
output fourth external data generated from the fourth internal data to an external device.

7. The semiconductor chip of claim 1, wherein the first semiconductor device further comprises:
a control circuit configured to:
generate an enablement signal, first and second write control signals, first and second read control signals, and a selection signal, one of which is selectively enabled according to the operation mode; and
output the enablement signal, the first and second write control signals, the first and second read control signals, and the selection signal to the second semiconductor device via the first through electrode;
a first input/output (I/O) circuit configured to:
electrically connect the second through electrode to first and second transmission I/O lines; and
receive or output the first and second data via the second through electrode; and
a first path control circuit configured to:
generate the first data from first external data provided by an external device to output the first data to the first transmission I/O line based on the enablement signal, the first and second write control signals, the first and second read control signals, and the selection signal during a first write operation;
generate second external data from the second data loaded on the first transmission I/O line to output the second external data to the external device based on the enablement signal, the first and second write control signals, the first and second read control signals, and the selection signal during a first read operation;
generate the first data from third external data provided by the external device to output the first data to the first transmission I/O line TIO1 and to generate first internal data from the third external data based on the enablement signal, the first and second write control signals, the first and second read control signals, and the selection signal during a second write operation;
generate the first data from second internal data to output the first data to the first transmission I/O line; and
generate fourth external data from the second internal data to output the fourth external data to the external device based on the enablement signal, the first and second write control signals, the first and second read control signals, and the selection signal during a second read operation,
wherein the error detection circuit is configured to detect errors of the first and second data loaded on the first transmission I/O line, generate a detection signal, and output the detection signal to the external device.

8. The semiconductor chip of claim 7, wherein the control circuit comprises:
a register configured to generate a mode enablement signal including information on the operation mode, first, second, third write mode signals, first, second, and third read mode signals, and a reset signal; and
a control signal generation circuit configured to generate the enablement signal, the first and second write control signals, the first and second read control signals, and the selection signal, one of which is selectively enabled according to a logic level combination of the mode enablement signal, the first, second, and third write mode signals, the first, second, and third read mode signals, and the reset signal.

9. The semiconductor chip of claim 8, wherein the control signal generation circuit comprises:
an enablement signal generation circuit configured to delay the mode enablement signal to generate the enablement signal;
a transmission control signal generation circuit configured to generate a transmission control signal which is enabled when the first read mode signal is inputted to the transmission control signal generation circuit and which is disabled when the first write mode signal is inputted to the transmission control signal generation circuit;
a write control signal generation circuit configured to generate the first and second write control signals, one of which is selectively enabled according to a logic level combination of the enablement signal, the second write mode signal, and the third write mode signal when the transmission control signal is disabled; and
a read control signal generation circuit configured to generate the first or second read control signal which is selectively enabled according to a logic level combination of the mode enablement signal, the second read mode signal, and the third read mode signal and configured to generate the selection signal which is enabled when the mode enablement signal is disabled and the transmission control signal is enabled.

10. The semiconductor chip of claim 7, wherein the first path control circuit comprises:
a first write path control circuit configured to:
generate the first data from the first external data to output the first data to the first transmission I/O line or generate the first data from the third external data to output the first data to the first transmission I/O line according to the enablement signal and the first and second write control signals; and
inversely buffer the third external data to generate the first internal data; and
a first read path control signal configured to inversely buffer the second data loaded on the first transmission I/O line to output the inversely buffered data of the second data as the second external data or output the second internal data as the fourth external data according to the selection signal and the first and second read control signals.

11. The semiconductor chip of claim 1, wherein the second semiconductor device comprises:
a second I/O circuit configured to:
electrically connect the second through electrode to third and fourth transmission I/O lines; and
receive or output the first and second data via the second through electrode; and
a second path control circuit configured to:
generate third internal data from the first data inputted through the third transmission I/O line during a first write operation; and
output fourth data as the second data through the third transmission I/O line, during a first read operation, according to the enablement signal, the first and second write control signals, the first and second read control signals, and the selection signal.

12. The semiconductor chip of claim 11, wherein the second path control circuit comprises:
a second write path control circuit configured to output the first data loaded on the third transmission I/O line as the third internal data according to the enablement signal and the first and second write control signals; and
a second read path control signal configured to output the fourth internal data to the third transmission I/O line to generate the second data according to the selection signal and the first and second read control signals.

13. A semiconductor chip comprising:
a first semiconductor device comprising a first error detection circuit; and
a second semiconductor device comprising a second error detection circuit, wherein the second semiconductor device is stacked with the first semiconductor device and electrically connected to the first semiconductor device via a first through electrode and a second through electrode,
wherein the first and second semiconductor devices are configured to at least one receive and output first data and second data via the second through electrode during a first write operation and a first read operation and are configured to detect errors of the first data and the second data using the first and second error detection circuits.

14. The semiconductor chip of claim 13, wherein, during a first write operation:
the first semiconductor device is configured to generate the first data from first external data provided by an external device and is configured to detect errors of the first data using the first error detection circuit; and
the second semiconductor device is configured to store first internal data generated from the first data and is configured to detect errors of the first data using the second error detection circuit.

15. The semiconductor chip of claim 13, wherein, during a first read operation:
the second semiconductor device is configured to output second internal data stored in the second semiconductor device as the second data via the second through electrode and is configured to detect errors of the second data using the second error detection circuit; and
the first semiconductor device is configured to detect errors of the second data using the first error detection circuit and is configured to output the second data as second external data.

16. The semiconductor chip of claim 13, wherein, during a second write operation, the first semiconductor device is configured to:
generate the first data from third external data provided by an external device;
detect errors of the first data using the first error detection circuit; and
store third internal data generated from the third external data.

17. The semiconductor chip of claim 13, wherein, during a second read operation, the first semiconductor device is configured to:
generate the first data from fourth internal data stored in the first semiconductor device;
detect errors of the first data using the first error detection circuit; and
output fourth external data generated from the fourth internal data to an external device.

18. The semiconductor chip of claim 13, wherein the first semiconductor device further comprises:
a control circuit configured to:
generate an enablement signal, first and second write control signals, first and second read control signals, and a selection signal, one of which is selectively enabled according to the first write operation, the first read operation, a second write operation, and a second read operation; and
output the enablement signal, the first and second write control signals, the first and second read control signals, and the selection signal to the second semiconductor device via the first through electrode;
a first input/output (I/O) circuit configured to:
electrically connect the second through electrode to first and second transmission I/O lines; and
receive or output the first and second data via the second through electrode; and
a first path control circuit configured to:
generate the first data from first external data provided by an external device to output the first data to the first transmission I/O line based on the enablement signal, the first and second write control signals, the first and second read control signals, and the selection signal during the first write operation;
generate second external data from the second data loaded on the first transmission I/O line to output the second external data to the external device based on the enablement signal, the first and second write control signals, the first and second read control signals, and the selection signal during the first read operation;
generate the first data from third external data provided by the external device to output the first data to the first transmission I/O line TIO1 and to generate first internal data from the third external data based on the enablement signal, the first and second write control signals, the first and second read control signals, and the selection signal during the second write operation;
generate the first data from second internal data to output the first data to the first transmission I/O line; and
generate fourth external data from the second internal data to output the fourth external data to the external device based on the enablement signal, the first and second write control signals, the first and second read control signals, and the selection signal during the second read operation,
wherein the first error detection circuit is configured to detect errors of the first and second data loaded on the first transmission I/O line to generate a first detection signal and is configured to output the first detection signal to the external device.

19. The semiconductor chip of claim 18, wherein the control circuit comprises:
a register configured to generate a mode enablement signal including information on the first write operation, the first read operation, the second write operation, the second read operation, first, second, and third write mode signals, first, second, and third read mode signals, and a reset signal; and
a control signal generation circuit configured to generate the enablement signal, the first and second write control signals, the first and second read control signals, and the selection signal, one of which is selectively enabled according to a logic level combination of the mode enablement signal, the first, second, and third write mode signals, the first, second, and third read mode signals, and the reset signal.

20. The semiconductor chip of claim 19, wherein the control signal generation circuit comprises:
an enablement signal generation circuit configured to delay the mode enablement signal to generate the enablement signal;
a transmission control signal generation circuit configured to generate a transmission control signal which is enabled when the first read mode signal is inputted to the transmission control signal generation circuit and which is disabled when the first write mode signal is inputted to the transmission control signal generation circuit;
a write control signal generation circuit configured to generate the first and second write control signals, one of which is selectively enabled according to a logic level combination of the enablement signal, the second write mode signal, and the third write mode signal when the transmission control signal is disabled; and
a read control signal generation circuit configured to generate the first or second read control signal which is selectively enabled according to a logic level combination of the mode enablement signal, the second read mode signal, and the third read mode signal and configured to generate the selection signal which is enabled when the mode enablement signal is disabled and the transmission control signal is enabled.

21. The semiconductor chip of claim 18, wherein the first path control circuit comprises:
a first write path control circuit configured to:
generate the first data from the first external data to output the first data to the first transmission I/O line or generate the first data from the third external data to output the first data to the first transmission I/O line according to the enablement signal and the first and second write control signals; and
inversely buffer the third external data to generate the first internal data; and
a first read path control signal configured to inversely buffer the second data loaded on the first transmission I/O line to output the inversely buffered data of the second data as the second external data or output the second internal data as the fourth external data according to the selection signal and the first and second read control signals.

22. The semiconductor chip of claim 13, wherein the second semiconductor device further comprises:
a second I/O circuit configured to:
electrically connect the second through electrode to third and fourth transmission I/O lines; and
receive or output the first and second data via the second through electrode; and
a second path control circuit configured to:
output the first data to the third transmission I/O line during the first write operation; and
output the second data loaded on the third transmission I/O line via the second through electrode, during the first read operation, according to the enablement signal, the first and second write control signals, the first and second read control signals, and the selection signal inputted via the first through electrode,
wherein second error detection circuit is configured to detect errors of the first and second data loaded on the third transmission I/O line to generate a second detection signal and is configured to output the second detection signal to an external device.

23. The semiconductor chip of claim 22, wherein the second path control circuit comprises:
a second write path control circuit configured to output the first data loaded on the second transmission I/O line as the third internal data according to the enablement signal and the first and second write control signals; and
a second read path control signal configured to output the fourth internal data to the third transmission I/O line to generate the second data according to the selection signal and the first and second read control signals.
